(19) United States
(12) Patent Application Publication
(10) Pub. No.: US 2024/0222283 A1
(43) Pub. Date: Jul. 4, 2024

(54) METHODS AND APPARATUS TO PREVENT OVER-ETCH IN SEMICONDUCTOR PACKAGES

(71) Applicant: Intel Corporation, Santa Clara, CA (US)

(72) Inventors: Hongxia Feng, Chandler, AZ (US); Bohan Shan, Chandler, AZ (US); Bai Nie, Chandler, AZ (US); Xiaoxuan Sun, Phoenix, AZ (US); Holly Sawyer, Aloha, OR (US); Tarek Ibrahim, Mesa, AZ (US); Adwait Telang, Portland, OR (US); Dingying Xu, Chandler, AZ (US); Leonel Arana, Phoenix, AZ (US); Xiaoying Guo, Chandler, AZ (US); Ashay Dani, Chandler, AZ (US); Sairam Agraharam, Chandler, AZ (US); Haobo Chen, Chandler, AZ (US); Srinivas Pietambaram, Chandler, AZ (US); Gang Duan, Chandler, AZ (US)

(21) Appl. No.: 18/147,487

(22) Filed: Dec. 28, 2022

(51) Int. Cl. H01L 23/538; H01L 23/00; H01L 23/498; H01L 25/065

(52) U.S. Cl. CPC H01L 23/5386; H01L 23/49816; H01L 24/16; H01L 25/0655; H01L 2224/16227; H01L 2924/15311

(57) ABSTRACT

Methods and apparatus to prevent over-etch in semiconductor packages are disclosed. A disclosed example semiconductor package includes at least one dielectric layer, an interconnect extending at least partially through or from the at least one dielectric layer, and a material on at least a portion of the interconnect, wherein the material comprises at least one of silicon or titanium.

### FIELD OF THE DISCLOSURE

This disclosure relates generally to semiconductor devices and, more particularly, to methods and apparatus to prevent over-etch.

### BACKGROUND

Semiconductor package architectures, such as multi-chip modules (MCMs), implement patch fabrication that can involve an active die communicatively coupled to a bridge die. In particular, a carrier having known good dies (KGDs) is provided with interconnect layers that electrically couple the KGDs to the bridge die. For power delivery and connection to the aforementioned bridge die, pillars (e.g., bridge pillars) are typically implemented. Subsequent to formation of such pillars, seed layers are typically etched away. Because fluid flow at a relatively tall pillar region is not generally prevalent, a relatively longer etch time can be necessitated. In turn, the relatively longer etch time can pose a risk of over-etching on the aforementioned pillars, thereby leading to potential reliability issues.

### BRIEF DESCRIPTION OF THE DRAWINGS

FIG. 1 is a cross-sectional view of a portion of an example architecture in accordance with teachings of this disclosure.

FIG. 2 is a cross-sectional view of an upper die portion in which examples disclosed herein can be implemented.

FIGS. 3A-3F depict an example process in accordance with teachings of this disclosure.

FIGS. 4A-4D depict another example process in accordance with teachings of this disclosure.

FIGS. 5A-5F depict yet another example process in accordance with teachings of this disclosure.

FIG. 6 illustrates example structures that can be produced by examples disclosed herein.

FIG. 7 is a flowchart representative of an example method to produce examples disclosed herein.

FIG. 8 is a top view of a wafer and dies that may be included in an integrated circuit (IC) package constructed in accordance with teachings disclosed herein.

FIG. 9 is a cross-sectional side view of an IC device that may be included in an IC package constructed in accordance with teachings disclosed herein.

FIG. 10 is a cross-sectional side view of an IC package that may include structures, in accordance with various examples.

FIG. 11 is a cross-sectional side view of an IC device assembly that may include an IC package constructed in accordance with teachings disclosed herein.

FIG. 12 is a block diagram of an example electrical device that may include an IC package constructed in accordance with teachings disclosed herein.

In general, the same reference numbers will be used throughout the drawing(s) and accompanying written description to refer to the same or like parts. The figures are not to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of a semiconductor device, “above” is not with reference to Earth, but instead is with reference to a bulk region of a base semiconductor substrate (e.g., a semiconductor wafer) on which components of an integrated circuit are formed. Specifically, as used herein, a first component of an integrated circuit is “above” a second component when the first component is farther away from the bulk region of the semiconductor substrate than the second component.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly that might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified in the below description. As used herein “substantially real time” refers to occurrence in a near instantaneous manner recognizing there may be real world delays for computing time, transmission, etc. Thus, unless otherwise specified, “substantially real time” refers to real time+/−1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

### DETAILED DESCRIPTION

Methods and apparatus to reduce over-etch in semiconductor packages are disclosed. Semiconductor package architectures, such as multi-chip modules (MCMs), implement patch fabrication that can involve an active die that is electrically coupled to a pillar and a bridge die. Subsequent to formation of the pillar, a corresponding seed layer is typically etched away. The etching of the seed layer can pose a risk of over-etching for the aforementioned pillars, thereby leading to potential reliability and/or performance issues.

Examples disclosed herein enable robust semiconductor packages/structures that reduce and/or mitigate over-etching. As mentioned above, over-etching can result from etching of a seed layer with an increased etching time, thereby causing an etching agent to permeate into portions of a semiconductor structure and/or package. As a result, areas of an interconnect, such as a pillar or a bump, can be reduced in size (e.g., reduced in overall width and/or volume), thereby potentially resulting in decreased reliability due to reduced material thickness and/or width. Further, performance issues can result from the size reduction associated with over-etching.

Examples disclosed herein utilize a material (e.g., an etch protection material), layer, cover, layering and/or coating to at least partially cover an interconnect of a semiconductor structure and, thus, protect at least portions of the interconnect or a structure proximate the interconnect during an etch process or step. Further, the material and/or layer can be retained (i.e., not etched or removed in subsequent processing) in the semiconductor structure, thereby facilitating subsequent assembly, coupling and/or deposition of a dielectric (e.g., at least one dielectric layer, a dielectric substrate, etc.) onto or around the interconnect. Examples disclosed herein can also reduce etching time, thereby reducing production/labor time and, in turn, costs related thereto.

Examples disclosed herein can be implemented in an MCM, an omni-directional interconnect (ODI) or any other appropriate type of semiconductor device, package, layering and/or structure. Examples disclosed herein include an interconnect (e.g., a pillar, a trace, a routing, etc.) that is provided with and/or at least partially covered by a material (e.g., an etch protection material). In particular, the material can laterally (e.g., diametrically) cover at least a portion of the interconnect. As a result, etching of the interconnect can be reduced, thereby preserving a significant amount of structure of the interconnect for increased resistance to physical damage, as well as improved signal performance (e.g., reduced signal degradation).

In some examples, the interconnect is at least partially composed of copper. However, any other conductive material can be implemented instead. Additionally or alternatively, the material is at least partially composed of and/or include elemental compositions of silicon, silicon nitride (SiNx) and/or titanium, for example. However, any other appropriate material(s) can be implemented instead. In some examples, a photoresist material is utilized proximate the material. In some such examples, a heat/thermal process is applied to the photoresist to form gaps around an interconnect. In turn, the formed gaps are provided with the material. In some examples, the interconnect is associated with a semiconductor package that can include multiple dies. In some such examples, the dies can be communicatively coupled to a bridge die.

As used herein, the term “material” refers to a layer, fluid, application, coating, film, etc. utilized to prevent and/or reduce etching of a material and/or component during an etching process. As used herein, the term “interconnect” refers to a trace, routing, pillar, bridge pillar, bump, joint, via, etc. utilized to electrically and/or communicatively couple components.

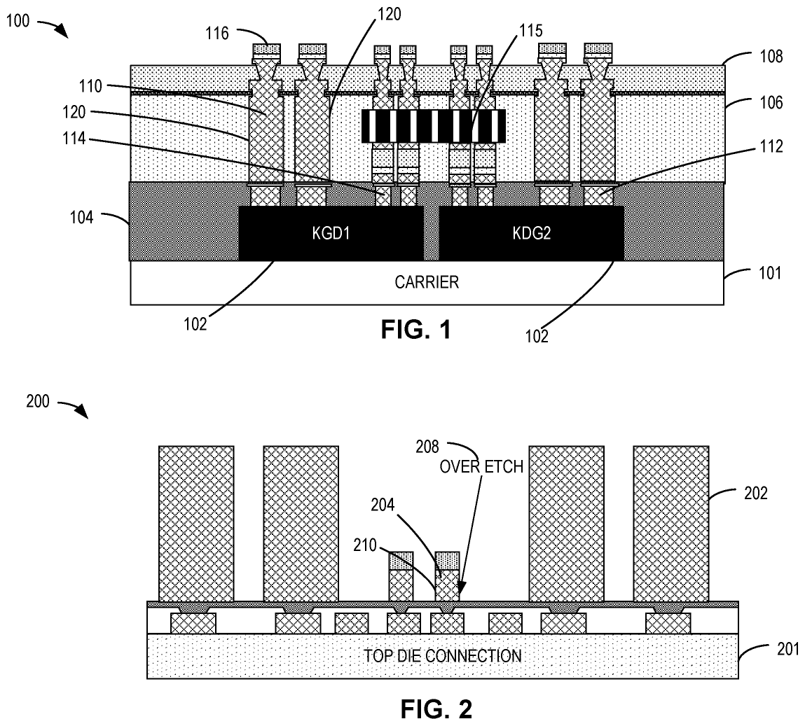

FIG. 1 is a cross-sectional view of a portion of an example architecture in accordance with teachings of this disclosure. Turning to FIG. 1, an example semiconductor package (e.g., a die chip) 100 is shown. The semiconductor package 100 of the illustrated example includes a carrier 101 that supports dies 102, both of which are known as known good dies (KGDs) such that the dies 102 are pre-tested prior to being integrated into the example semiconductor package 100 (e.g., as an MCM having multiple dies that are integrated thereon). The example semiconductor package 100 further includes a dielectric (e.g., at least one dielectric layer, a dielectric substrate, a substrate, etc.) 104, a dielectric 106 and a photoresist (e.g., a photoresist layer, a photoresist substrate, etc.) 108. In the illustrated example of FIG. 1, the semiconductor package 100 includes interconnects 110, which are implemented as pillars in this example, that extend longitudinally along a depth of the semiconductor package 100 (up and down in the view of FIG. 1). Further, interconnects 112 also extend longitudinally and are utilized to electrically couple the dies 102 to corresponding ones of the interconnects 110. In this example, interconnects 114, which are at least partially composed of a metal such as copper for example, are implemented to electrically and communicatively couple the dies 102 to a bridge die 115 while interconnects 116 are utilized for additional layers and/or interconnects, for example.

To prevent over-etching of structures and/or portions of the semiconductor package 100, such as the interconnects 110 for example, a material (e.g., an etch protection material, an etch protector, an etch resistor, etc.) 120 is applied to cover at least a portion thereof. According to examples disclosed herein, the example material 120 prevents at least portions of structures and/or interconnects from being etched (e.g., over-etched), thereby preventing a reduction in volume and/or width thereof that can result in physical damage and/or signal degradation. In other words, an occurrence of overly narrow or relatively small portions of the structures and/or interconnects of the semiconductor package 100 can be reduced. As a result, examples disclosed herein can improve reliability, as well as enable increased/improved performance of the semiconductor package 100 by improving signal integrity, for example.

To facilitate bonding of the dielectric 104 and/or the dielectric 106 to the interconnects 110, the material 120 can be provided and/or applied to the interconnects 110 to facilitate adhesion, coupling and/or bonding of the interconnect 110 to the dielectric 104 and/or the dielectric 106. In particular, the material 120, which can be at least partially composed of and/or have elemental compositions of a material, such as silicon nitride and/or titanium, can be utilized to increase an adhesion and/or coupling of layers of the dielectric 104 and/or the dielectric 106.

FIG. 2 is a cross-sectional view of an example upper die structure 200 in which examples disclosed herein can be implemented. In the illustrated example of FIG. 2, a top die connection 201 is electrically coupled to interconnects 202, 204. Further, a portion 208 that can be generally susceptible to over-etch (e.g., during a seed layer etching process) is depicted. In this example, a material (e.g., an etch protection material, an etch protection layer) 210 can be provided to cover at least a portion of ones of the interconnects 202, 204, thereby preventing over-etch thereof. In particular, the material 210 can cover and/or surround lateral portions (e.g., a diameter) of the interconnects 202, 204.

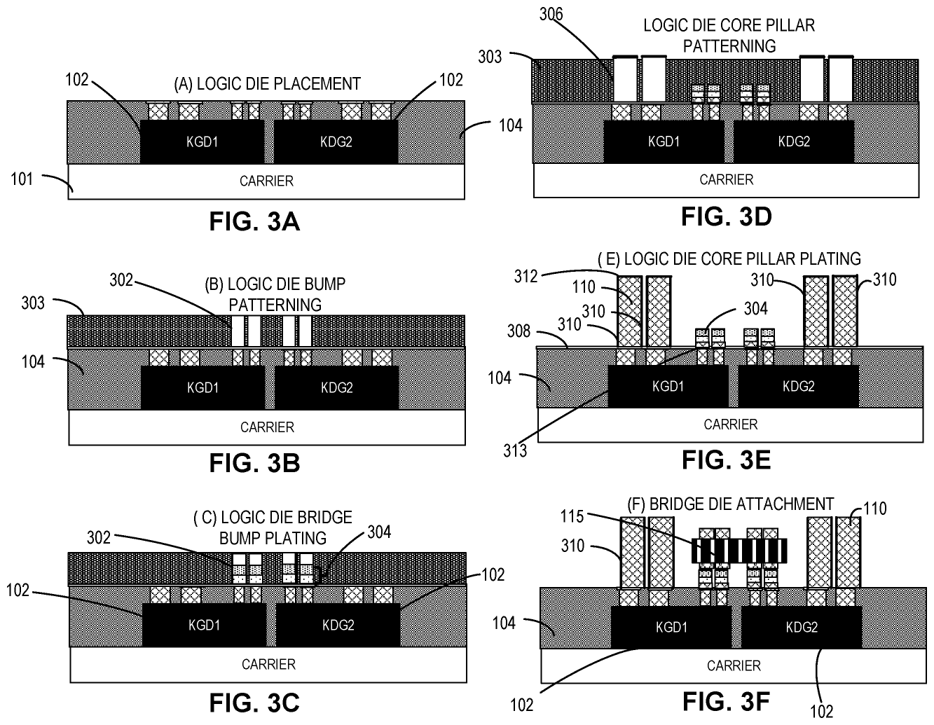

FIGS. 3A-3F depict an example process in accordance with teachings of this disclosure. Turning to FIG. 3A, two of the dies 102 are shown embedded (e.g., overmolded) in the dielectric 104. In particular, the dies 102 are KGD (e.g., dies that are pre-screened and/or pre-tested) and multiple ones of the dies 102 are placed and positioned onto the carrier 101 prior to deposition and/or layering of the dielectric 104 thereon. In other words, the carrier 101 carries and/or supports multiple ones of the dies 102.

FIG. 3B depicts a photoresist 303 being provided onto the dielectric 104. In the illustrated example of FIG. 3B, patterning of the photoresist 303 defines apertures 302 thereon. In some examples, bridge die bumps are patterned in relatively thin photoresist that is stripped subsequent to pillar plating.

Turning to FIG. 3C, in this example, the aforementioned apertures 302 are provided with plating (e.g., logic die bridge bump plating) that consist of and/or define interconnects 304 that are electrically coupled to each of the dies 102 such that the interconnects 304 extend from and/or through the dielectric 104. In some examples, the interconnects 304 are at least partially composed of a solder material and/or layering. The aforementioned bump plating can have a copper/nickel/tin stack up, for example. However, any other appropriate stack up can be implemented instead.

FIG. 3D depicts application and patterning of the example photoresist 303. In this example, apertures 306 are defined in the photoresist 303, thereby enabling subsequent deposition of a pillar or other interconnect structure, for example. In the illustrated example of FIG. 3D, the photoresist 303 can be etched to define the apertures 306 with corresponding gaps of one or more pillars.

Turning to FIG. 3E, the photoresist 303 shown in FIGS. 3B-3D is removed (e.g., etched). Further, the interconnects 110 are shown extending from a seed layer 308 and the interconnects 304 extending from the dielectric 104 are exposed. According to examples disclosed herein, an etch protection layer 310 is applied to lateral sides and/or diameters of the interconnects 110. Additionally or alternatively, an etch protection layer 312 (or the etch protection layer 310) is applied to longitudinal and/or distal ends of the interconnects 110. An etch protection layer can also be placed on or cover sidewall copper pad/pillar 313 under the interconnects 304 because the interconnects 304 are solder, the layer under 304 is copper, for example and, thus, can be etched during seed removal.

In some examples, the interconnects 110 are plated with copper. However, any other appropriate material and/or plating process can be implemented instead.

FIG. 3F depicts attachment and/or coupling of the aforementioned example bridge die 115 to the dies 102. In this example, the bridge die 115 is communicatively and electrically coupled to multiple ones of the dies 102. Further, the seed layer 308 shown in FIG. 3E has been etched. However, the interconnects 110 do not exhibit any significant structural and/or geometric change caused by over-etching due to the etch protection layer 310. In particular, the example interconnects 110 can have a greater cross-sectional area at an interface proximate or at the dielectric 104. As a result, the interconnects 110 can be less susceptible to physical damage and/or signal degradation during operation thereof. In other words, examples disclosed herein can enable significant damage and/or defect prevention, as well as improved signal integrity.

In some examples, bonding of the bridge die 115 can occur by way of split soldering such that bridge die pillars/bumps are patterned and plated separately from core pillars in at least two distinct steps.

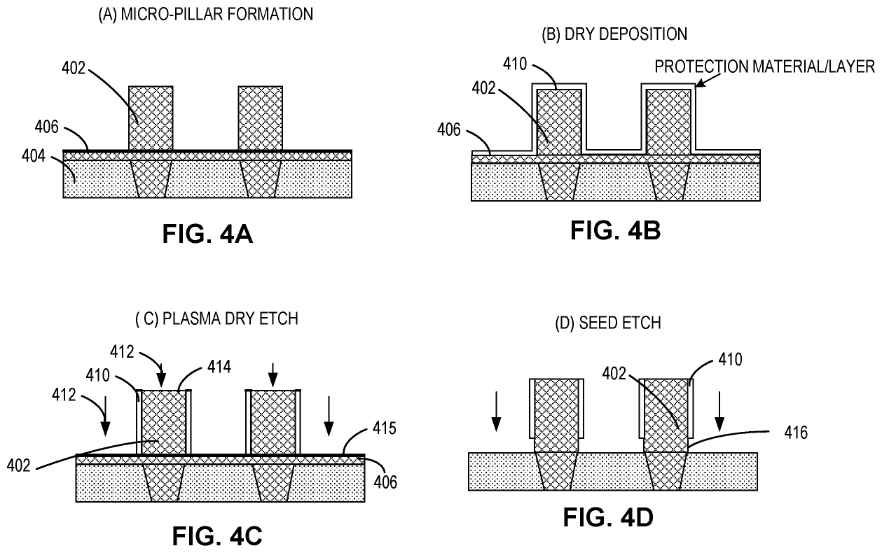

FIGS. 4A-4D depict another example process in accordance with teachings of this disclosure. In particular, FIGS. 4A-4D depict implementation and/or performance of a “dry” etch process. In particular, the examples of FIGS. 4A-4D can correspond to a plasma dry etch process. Turning to FIG. 4A, formation of pillars 402 is shown. In this example, the pillars 402 are at least partially composed of copper and extend from a dielectric 404. Further, a seed layer 406 from which the pillars 402 extend is adjacent the dielectric 404. While the example pillars 402 include copper, any other appropriate conductive material can be implemented instead.

Turning to FIG. 4B, an etch protection layer 410 is shown placed and/or deposited over the pillars 402, as well as the seed layer 406. In this example, the etch protection layer 410 is applied in a dry deposition process. For example, the etch protection layer 410 can be applied as a deposited sheet, film and/or applied layering material.

FIG. 4C depicts application of a plasma dry etch process. In the illustrated example of FIG. 4C, a portion of the etch protection layer 410 is removed, thereby exposing a portion 414 corresponding to the pillars 402. Further, the plasma dry etch process also exposes portions 415 covering the seed layer 406. In this example, arrows 412 generally indicate a direction of application of the aforementioned plasma dry etch process.

Turning to FIG. 4D, a seed layer etch process is performed. In this example, at least portions of the etch protection layer 410 covering at least portions of the pillars 402 remain after the seed layer etch process is performed. The seed layer etch process can be a copper seed etching process. According to examples disclosed herein, portions 416 of the respective pillars 402 are exposed. In particular, the exposed portions 416 correspond to indentations that result from the seed etching process. However, a reduction in width of the pillars 402 resulting from the seed etching process is mitigated by the etch protection layer 410.

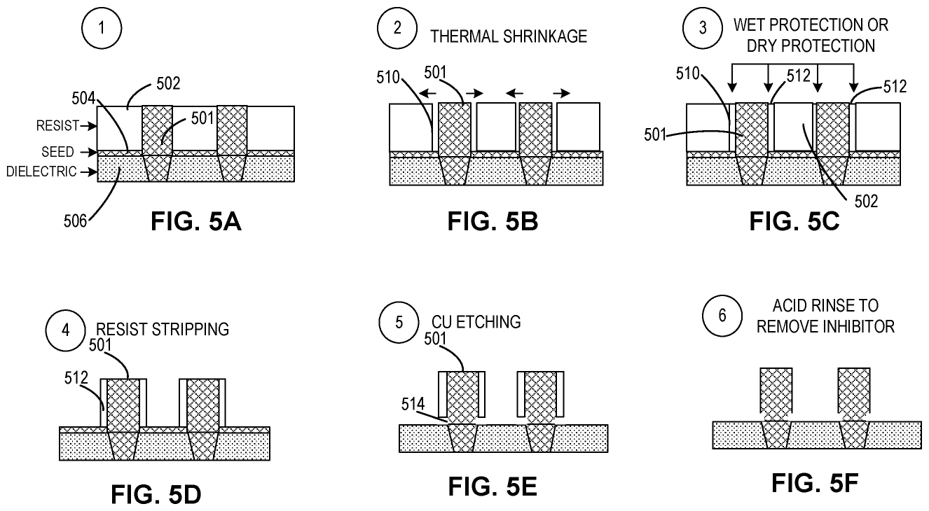

FIGS. 5A-5F depict yet another example process in accordance with teachings of this disclosure. Particularly, the example process of FIGS. 5A-5F depicts utilization of a we″ etch process. Turning to FIG. 5A, pillars 501 are depicted extending through a photoresist (e.g., a photoresist layer) 502. In this example, a seed layer 504 is positioned and/or layered between the photoresist 502 and a dielectric (e.g., a dielectric layer) 506.

FIG. 5B depicts an example thermal treatment (e.g., a thermal shrinkage process, a heating process, etc.) that can be implemented in examples disclosed herein. In this example, the photoresist 502 is heated to a temperature such that shrinkage thereof causes gaps 510 to be defined. As a result, at least a portion of each of the pillars 501 is exposed (e.g., at least portions of diametric/outer surfaces and/or outer diameters of the pillars 501 are exposed) for subsequent application of etch-protection materials and/or substances.

In the illustrated example of FIG. 5C, a material (e.g., an etch protection material) 512 is applied into the gaps 510 of the photoresist 502, thereby covering lateral portions and/or outer sides/edges of the pillars 501. In this example, the gaps 510 facilitate application of the material 512 to the pillars 501. In some examples. The material 512 can be applied as a liquid or coating material, for example.

FIG. 5D depicts removal of the photoresist 502 shown and described above in connection with FIGS. 5A-5C. In particular, the pillars 501 along with the material 512 are exposed for a subsequent seed layer etching process and/or step.

FIG. 5E depicts a seed layer etching process. As a result, the pillars 501 of the illustrated example each include an exposed section or indentation 514.

As can be seen in the example of FIG. 5F, in some examples, the material 512 shown in FIGS. 5C-5E is removed. For example, an acid rinse or other removal process can be implemented to remove the material 512.

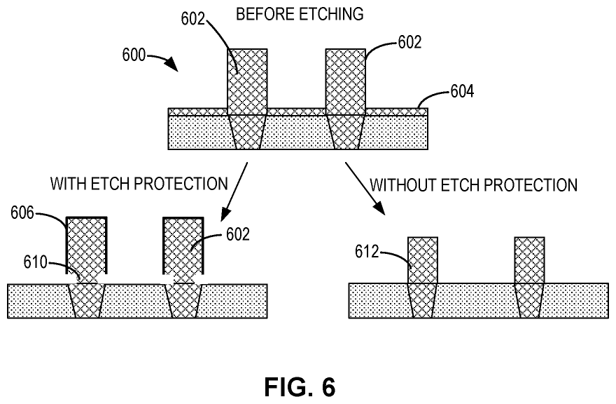

FIG. 6 illustrates example structures that can be produced by examples disclosed herein. In the illustrated example, a semiconductor structure/package 600 corresponds to a mid-production/fabrication structure. In particular, pillars 602 extend from a seed layer 604. In this example, the pillars 602 have been provided with a material (e.g., an etch protection material) 606, thereby defining an exposed area or interface 610 resulting from a seed etch process.

In contrast to the pillars 602, pillars 612 have not been provided with a material. Accordingly, the pillars 612 can be relatively smaller in height and/or width (in the view of FIG. 6) than the pillars 602 subsequent to a seed etch process. As a result, the pillars 602 can be less susceptible to damage (e.g., fracture) than the pillars 612. As can be seen in the illustrated example of FIG. 6, examples disclosed herein can result in an interconnect that has an increased size (e.g., in width and/or height) as shown in FIG. 6, but also may exhibit an indentation or portion smaller portion at a portion or base thereof, such the an exposed area or interface 610.

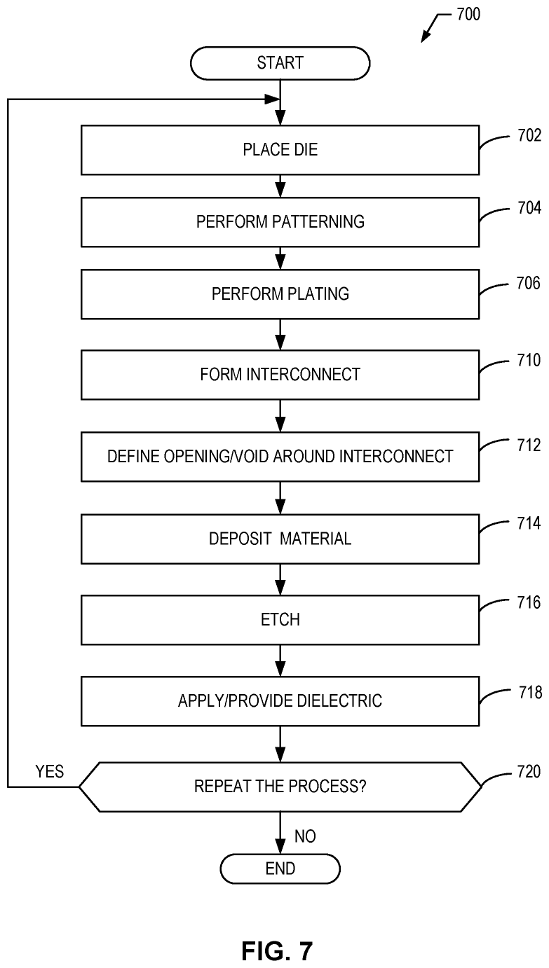

FIG. 7 is a flowchart representative of an example method 700 to produce examples disclosed herein. In this example, a semiconductor structure and/or package is being produced and/or fabricated such that at least portions thereof are to utilize a material to prevent over-etching. In this example, the material includes at least one of silicon or titanium.

At block 702, a die is placed onto a carrier and/or a carrier. In other examples, multiple die are placed onto the carrier (e.g., KGD for an MCM or multi-die architecture).

At block 704, patterning of a photoresist is performed. In some examples, the photoresist is patterned to enable and/or define openings surrounding (e.g., laterally surrounding) an interconnect, for example.

At block 706, plating is performed and/or provided. The plating can be utilized for routing and/or formation of interconnects, for example.

At block 710, a pillar and/or an interconnect is formed based on the plating step (block 706), for example.

At block 712, in some examples, a void, gap or opening surrounding at least a portion of the interconnect and/or the pillar is formed and/or defined. In particular, a thermal process can be utilized to decrease a size of the photoresist (e.g., shrink the photoresist), thereby defining the aforementioned void or opening.

At block 714, the aforementioned material is deposited and/or provided onto at least a portion of the pillar and/or the interconnect. In some examples, the material is applied to lateral sides and/or portions of the pillar and/or the interconnect. The material can be applied as a layer, a film, a liquid, a spray, or any other appropriate type of application process.

At block 716, an etch process is performed. In particular, a seed layer proximate the photoresist and/or a dielectric from which the pillar and/or the interconnect extends is etched. The etch process can be a “wet” or “dry” etch process. Additionally or alternatively, the etch process can be a plasma etch process.

At block 718, in some examples, a dielectric is provided. For example, a dielectric layer may be provided proximate and/or at the pillar and/or the interconnect. In particular, the provided dielectric is coupled to the pillar and/or the interconnect. Additionally or alternatively, the provided dielectric is coupled to a dielectric in which the pillar and/or the interconnect is embedded.

At block 720, it is determined whether to repeat the process. If the process is to be repeated (block 720), control of the process returns to block 702. Otherwise, the process ends.

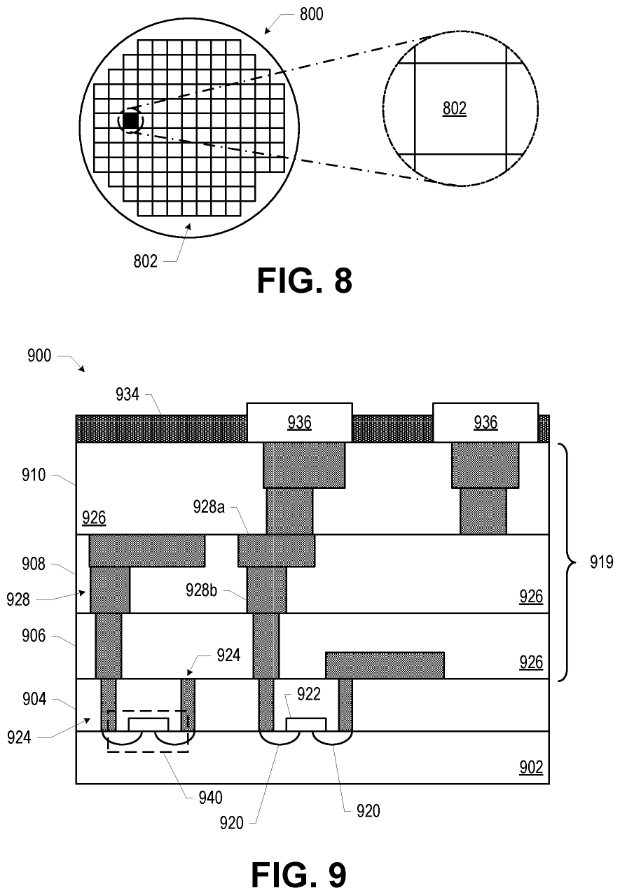

The examples disclosed herein may be included in any suitable electronic component. FIGS. 8-12 illustrate various examples of apparatus that may include or be included in the examples disclosed herein.

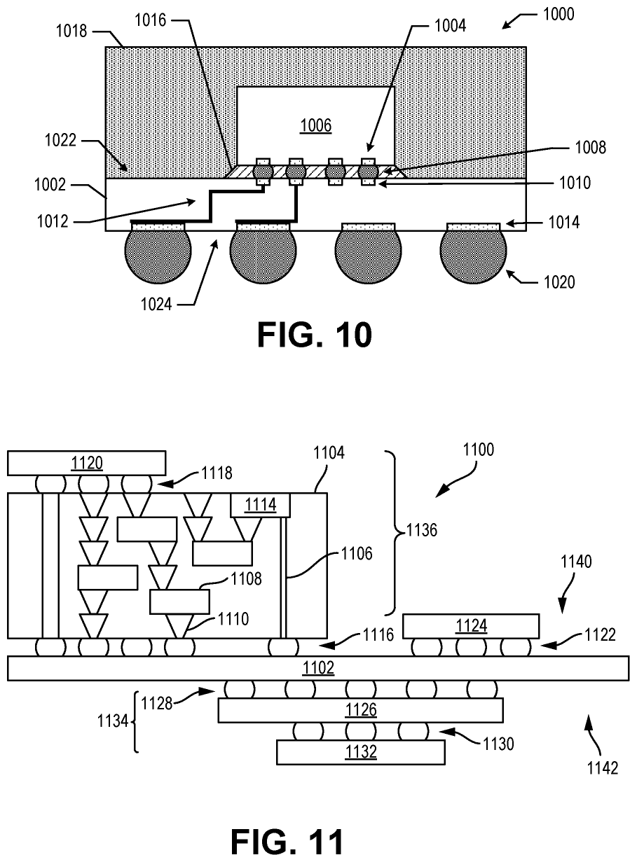

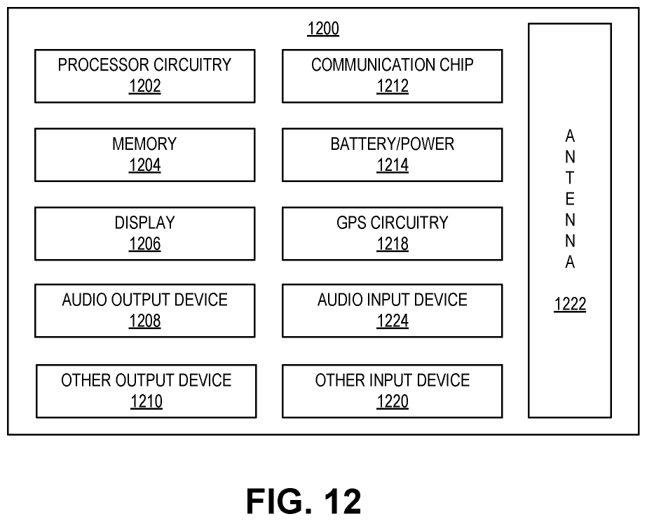

FIG. 8 is a top view of a wafer 800 and dies 802 that may be included in an IC package whose substrate includes one or more examples disclosed herein (e.g., as discussed below with reference to FIG. 10) in accordance with any of the examples disclosed herein. The wafer 800 may be composed of semiconductor material and may include one or more dies 802 having circuitry. Each of the dies 802 may be a repeating unit of a semiconductor product. After the fabrication of the semiconductor product is complete, the wafer 800 may undergo a singulation process in which the dies 802 are separated from one another to provide discrete “chips.” The die 802 may include one or more transistors (e.g., some of the transistors 940 of FIG. 9, discussed below), supporting circuitry to route electrical signals to the transistors, passive components (e.g., traces, resistors, capacitors, inductors, and/or other circuitry), and/or any other components. In some examples, the die 802 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry. Multiple ones of these devices may be combined on a single die 802. For example, a memory array formed by multiple memory circuits may be formed on a same die 802 as programmable circuitry (e.g., the processor circuitry 1202 of FIG. 12) or other logic circuitry. Such memory may store information or instructions for use by the programmable circuitry. Examples disclosed herein may be manufactured using a die-to-wafer assembly technique in which some dies are attached to a wafer 800 that include others of the dies, and the wafer 800 is subsequently singulated.

FIG. 9 is a cross-sectional side view of an IC device 900 that may be included in an IC package whose substrate includes one or more examples disclosed herein (e.g., as discussed below with reference to FIG. 10), in accordance with any of the examples disclosed herein. One or more of the IC devices 900 may be included in one or more dies 802 (FIG. 8). The IC device 900 may be formed on a die substrate 902 (e.g., the wafer 800 of FIG. 8) and may be included in a die (e.g., the die 802 of FIG. 8). The die substrate 902 may be a semiconductor substrate composed of semiconductor material systems including, for example, n-type or p-type materials systems (or a combination of both). The die substrate 902 may include, for example, a crystalline substrate formed using a bulk silicon or a silicon-on-insulator (SOI) substructure. In some examples, the die substrate 902 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the die substrate 902. Although a few examples of materials from which the die substrate 902 may be formed are described here, any material that may serve as a foundation for an IC device 900 may be used. The die substrate 2002 may be part of a singulated die (e.g., the dies 802 of FIG. 8) or a wafer (e.g., the wafer 800 of FIG. 8).

The IC device 900 may include one or more device layers 904 disposed on or above the die substrate 902. The device layer 904 may include features of one or more transistors 940 (e.g., metal oxide semiconductor field-effect transistors (MOSFETs)) formed on the die substrate 902. The device layer 904 may include, for example, one or more source and/or drain (S/D) regions 920, a gate 922 to control current flow between the S/D regions 920, and one or more S/D contacts 924 to route electrical signals to/from the S/D regions 920. The transistors 940 may include additional features not depicted for the sake of clarity, such as device isolation regions, gate contacts, and the like. The transistors 940 are not limited to the type and configuration depicted in FIG. 9 and may include a wide variety of other types and/or configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 940 may include a gate 922 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 940 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some examples, when viewed as a cross-section of the transistor 940 along the source-channel-drain direction, the gate electrode may include a U-shaped structure that includes a bottom portion substantially parallel to the surface of the die substrate 902 and two sidewall portions that are substantially perpendicular to the top surface of the die substrate 902. In other examples, at least one of the metal layers that form the gate electrode may be a planar layer that is substantially parallel to the top surface of the die substrate 902 and does not include sidewall portions substantially perpendicular to the top surface of the die substrate 902. In other examples, the gate electrode may include a combination of U-shaped structures and planar, non-U-shaped structures. For example, the gate electrode may include one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some examples, a plurality of spacer pairs may be used; for instance, two pairs, three pairs, or four pairs of sidewall spacers may be formed on opposing sides of the gate stack.

The S/D regions 920 may be formed within the die substrate 902 adjacent to the gate 922 of each transistor 940. The S/D regions 920 may be formed using an implantation/diffusion process or an etching/deposition process, for example. In the former process, dopants such as boron, aluminum, antimony, phosphorous, or arsenic may be ion-implanted into the die substrate 902 to form the S/D regions 920. An annealing process that activates the dopants and causes them to diffuse further into the die substrate 902 may follow the ion-implantation process. In the latter process, the die substrate 902 may first be etched to form recesses at the locations of the S/D regions 920. An epitaxial deposition process may then be carried out to fill the recesses with material that is used to fabricate the S/D regions 920. In some implementations, the S/D regions 920 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 920 may be formed using one or more alternate semiconductor materials such as germanium or a group III-V material or alloy. In further examples, one or more layers of metal and/or metal alloys may be used to form the S/D regions 920.

Electrical signals, such as power and/or input/output (I/O) signals, may be routed to and/or from the devices (e.g., transistors 940) of the device layer 904 through one or more interconnect layers disposed on the device layer 904 (illustrated in FIG. 9 as interconnect layers 906-910). For example, electrically conductive features of the device layer 904 (e.g., the gate 922 and the S/D contacts 924) may be electrically coupled with the interconnect structures 928 of the interconnect layers 906-910. The one or more interconnect layers 906-910 may form a metallization stack (also referred to as an “ILD stack”) 919 of the IC device 900.

The interconnect structures 928 may be arranged within the interconnect layers 906-910 to route electrical signals according to a wide variety of designs (in particular, the arrangement is not limited to the particular configuration of interconnect structures 928 depicted in FIG. 9). Although a particular number of interconnect layers 906-910 is depicted in FIG. 9, examples of the present disclosure include IC devices having more or fewer interconnect layers than depicted.

In some examples, the interconnect structures 928 may include lines 928a and/or vias 928b filled with an electrically conductive material such as a metal. The lines 928a may be arranged to route electrical signals in a direction of a plane that is substantially parallel with a surface of the die substrate 902 upon which the device layer 904 is formed. For example, the lines 928a may route electrical signals in a direction in and out of the page from the perspective of FIG. 9. The vias 928b may be arranged to route electrical signals in a direction of a plane that is substantially perpendicular to the surface of the die substrate 902 upon which the device layer 904 is formed. In some examples, the vias 928b may electrically couple lines 928a of different interconnect layers 906-910 together.

The interconnect layers 906-910 may include a dielectric material 926 disposed between the interconnect structures 928, as shown in FIG. 9. In some examples, the dielectric material 926 disposed between the interconnect structures 928 in different ones of the interconnect layers 906-910 may have different compositions; in other examples, the composition of the dielectric material 926 between different interconnect layers 906-910 may be the same.

A first interconnect layer 906 (referred to as Metal 1 or “M1”) may be formed directly on the device layer 904. In some examples, the first interconnect layer 906 may include lines 928a and/or vias 928b, as shown. The lines 928a of the first interconnect layer 906 may be coupled with contacts (e.g., the S/D contacts 924) of the device layer 904.

A second interconnect layer 908 (referred to as Metal 2 or “M2”) may be formed directly on the first interconnect layer 906. In some examples, the second interconnect layer 908 may include vias 928b to couple the lines 928a of the second interconnect layer 908 with the lines 928a of the first interconnect layer 906. Although the lines 928a and the vias 928b are structurally delineated with a line within each interconnect layer (e.g., within the second interconnect layer 908) for the sake of clarity, the lines 928a and the vias 928b may be structurally and/or materially contiguous (e.g., simultaneously filled during a dual-damascene process) in some examples.

A third interconnect layer 910 (referred to as Metal 3 or “M3”) (and additional interconnect layers, as desired) may be formed in succession on the second interconnect layer 908 according to similar techniques and configurations described in connection with the second interconnect layer 908 or the first interconnect layer 906. In some examples, the interconnect layers that are “higher up” in the metallization stack 919 in the IC device 900 (i.e., further away from the device layer 904) may be thicker.

The IC device 900 may include a solder resist material 934 (e.g., polyimide or similar material) and one or more conductive contacts 936 formed on the interconnect layers 906-910. In FIG. 9, the conductive contacts 936 are illustrated as taking the form of bond pads. The conductive contacts 936 may be electrically coupled with the interconnect structures 928 and configured to route the electrical signals of the transistor(s) 940 to other external devices. For example, solder bonds may be formed on the one or more conductive contacts 936 to mechanically and/or electrically couple a chip including the IC device 900 with another component (e.g., a circuit board). The IC device 900 may include additional or alternate structures to route the electrical signals from the interconnect layers 906-910; for example, the conductive contacts 936 may include other analogous features (e.g., posts) that route the electrical signals to external components.

FIG. 10 is a cross-sectional view of an example IC package 1000 that may include one or more examples disclosed herein. The package substrate 1002 may be formed of a dielectric material, and may have conductive pathways extending through the dielectric material between upper and lower faces 1022, 1024, or between different locations on the upper face 1022, and/or between different locations on the lower face 1024. These conductive pathways may take the form of any of the interconnects 928 discussed above with reference to FIG. 9. In some examples, any number of examples disclosed herein (with any suitable structure) may be included in a package substrate 1002. In some examples, no examples disclosed herein may be included in the package substrate 1002.

The IC package 1000 may include a die 1006 coupled to the package substrate 1002 via conductive contacts 1004 of the die 1006, first-level interconnects 1008, and conductive contacts 1010 of the package substrate 1002. The conductive contacts 1010 may be coupled to conductive pathways 1012 through the package substrate 1002, allowing circuitry within the die 1006 to electrically couple to various ones of the conductive contacts 1014 or to the examples disclosed herein (or to other devices included in the package substrate 1002, not shown). The first-level interconnects 1008 illustrated in FIG. 10 are solder bumps, but any suitable first-level interconnects 1008 may be used. As used herein, a “conductive contact” refers to a portion of conductive material (e.g., metal) serving as an electrical interface between different components. Conductive contacts may be recessed in, flush with, or extending away from a surface of a component, and may take any suitable form (e.g., a conductive pad or socket).

In some examples, an underfill material 1016 may be disposed between the die 1006 and the package substrate 1002 around the first-level interconnects 1008, and a mold compound 1018 may be disposed around the die 1006 and in contact with the package substrate 1002. In some examples, the underfill material 1016 may be the same as the mold compound 1018. Example materials that may be used for the underfill material 1016 and the mold compound 1018 are epoxy mold materials, as suitable. Second-level interconnects 1020 may be coupled to the conductive contacts 1014. The second-level interconnects 1020 illustrated in FIG. 10 are solder balls (e.g., for a ball grid array arrangement), but any suitable second-level interconnects 1020 may be used (e.g., pins in a pin grid array arrangement or lands in a land grid array arrangement). The second-level interconnects 1020 may be used to couple the IC package 1000 to another component, such as a circuit board (e.g., a motherboard), an interposer, or another IC package, as known in the art and as discussed below with reference to FIG. 10.

In FIG. 10, the IC package 1000 is a flip chip package, and includes a structure in accordance with teachings of this disclosure in the package substrate 1002. The number and location of structures in accordance with teachings of this disclosure in the package substrate 1002 of the IC package 1000 is simply illustrative, and any number of structures in accordance with teachings of this disclosure (with any suitable structure) may be included in a package substrate 1002. In some examples, no structure in accordance with teachings of this disclosure may be included in the package substrate 1002. The die 1006 may take the form of any of the examples of the die 802 discussed herein (e.g., may include any of the examples of the IC device 900). In some examples, the die 1006 may include one or more structures in accordance with teachings of this disclosure (e.g., as discussed above with reference to FIG. 8 and FIG. 9); in other examples, the die 1006 may not include any of the structures in accordance with teachings of this disclosure.

Although the IC package 1000 illustrated in FIG. 10 is a flip chip package, other package architectures may be used. For example, the IC package 1000 may be a ball grid array (BGA) package, such as an embedded wafer-level ball grid array (eWLB) package. In another example, the IC package 1000 may be a wafer-level chip scale package (WLCSP) or a panel fanout (FO) package. Although a single die 1006 is illustrated in the IC package 1000 of FIG. 10, an IC package 1000 may include multiple dies 1006 (e.g., with one or more of the multiple dies 1006 coupled to a structure in accordance with teachings of this disclosure included in the package substrate 1002). An IC package 1000 may include additional passive components, such as surface-mount resistors, capacitors, and inductors disposed on the first face 1022 or the second face 1024 of the package substrate 1002. More generally, an IC package 1000 may include any other active or passive components known in the art.

FIG. 11 is a cross-sectional side view of an IC device assembly 1100 that may include the structures in accordance with teachings of this disclosure disclosed herein. In some examples, the IC device assembly corresponds to the structures in accordance with teachings of this disclosure. The IC device assembly 1100 includes a number of components disposed on a circuit board 1102 (which may be, for example, a motherboard). The IC device assembly 1100 includes components disposed on a first face 1140 of the circuit board 1102 and an opposing second face 1142 of the circuit board 1102; generally, components may be disposed on one or both faces 1140 and 1142.

In some examples, the circuit board 1102 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1102. In other examples, the circuit board 1102 may be a non-PCB substrate.

The IC device assembly 1100 illustrated in FIG. 11 includes a package-on-interposer structure 1136 coupled to the first face 1140 of the circuit board 1102 by coupling components 1116. The coupling components 1116 may electrically and mechanically couple the package-on-interposer structure 1136 to the circuit board 1102, and may include solder balls (as shown in FIG. 11), male and female portions of a socket, an adhesive, an underfill material, and/or any other suitable electrical and/or mechanical coupling structure.

The package-on-interposer structure 1136 may include an IC package 1120 coupled to an interposer 1104 by coupling components 1118. The coupling components 1118 may take any suitable form for the application, such as the forms discussed above with reference to the coupling components 1116. Although a single IC package 1120 is shown in FIG. 11, multiple IC packages may be coupled to the interposer 1104; indeed, additional interposers may be coupled to the interposer 1104. The interposer 1104 may provide an intervening substrate used to bridge the circuit board 1102 and the IC package 1120. The IC package 1120 may be or include, for example, a die (the die 802 of FIG. 8), an IC device (e.g., the IC device 900 of FIG. 9), or any other suitable component. Generally, the interposer 1104 may spread a connection to a wider pitch or reroute a connection to a different connection. For example, the interposer 1104 may couple the IC package 1120 (e.g., a die) to a set of BGA conductive contacts of the coupling components 1116 for coupling to the circuit board 1102. In the example illustrated in FIG. 11, the IC package 1120 and the circuit board 1102 are attached to opposing sides of the interposer 1104; in other examples, the IC package 1120 and the circuit board 1102 may be attached to a same side of the interposer 1104. In some examples, three or more components may be interconnected by way of the interposer 1104.

In some examples, the interposer 1104 may be formed as a PCB, including multiple metal layers separated from one another by layers of dielectric material and interconnected by electrically conductive vias. In some examples, the interposer 1104 may be formed of an epoxy resin, a fiberglass-reinforced epoxy resin, an epoxy resin with inorganic fillers, a ceramic material, or a polymer material such as polyimide. In some examples, the interposer 1104 may be formed of alternate rigid or flexible materials that may include the same materials described above for use in a semiconductor substrate, such as silicon, germanium, and other group III-V and group IV materials. The interposer 1104 may include metal interconnects 1108 and vias 1110, including but not limited to through-silicon vias (TSVs) 1106. The interposer 1104 may further include embedded devices 1114, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1104. The package-on-interposer structure 1136 may take the form of any of the package-on-interposer structures known in the art.

The IC device assembly 1100 may include an IC package 1124 coupled to the first face 1140 of the circuit board 1102 by coupling components 1122. The coupling components 1122 may take the form of any of the examples discussed above with reference to the coupling components 1116, and the IC package 1124 may take the form of any of the examples discussed above with reference to the IC package 1120.

The IC device assembly 1100 illustrated in FIG. 11 includes a package-on-package structure 1134 coupled to the second face 1142 of the circuit board 1102 by coupling components 1128. The package-on-package structure 1134 may include a first IC package 1126 and a second IC package 1132 coupled together by coupling components 1130 such that the first IC package 1126 is disposed between the circuit board 1102 and the second IC package 1132. The coupling components 1128, 1130 may take the form of any of the examples of the coupling components 1116 discussed above, and the IC packages 1126, 1132 may take the form of any of the examples of the IC package 1120 discussed above. The package-on-package structure 1134 may be configured in accordance with any of the package-on-package structures known in the art.

FIG. 12 is a block diagram of an example electrical device 1200 that may include one or more of the example structures in accordance with teachings of this disclosure. For example, any suitable ones of the components of the electrical device 1200 may include one or more of the device assemblies 1100, IC devices 900, or dies 802 disclosed herein, and may be arranged in the example structures in accordance with teachings of this disclosure. A number of components are illustrated in FIG. 12 as included in the electrical device 1200, but any one or more of these components may be omitted or duplicated, as suitable for the application. In some examples, some or all of the components included in the electrical device 1200 may be attached to one or more motherboards. In some examples, some or all of these components are fabricated onto a single system-on-a-chip (SoC) die.

Additionally, in various examples, the electrical device 1200 may not include one or more of the components illustrated in FIG. 12, but the electrical device 1200 may include interface circuitry for coupling to the one or more components. For example, the electrical device 1200 may not include a display 1206, but may include display interface circuitry (e.g., a connector and driver circuitry) to which a display 1206 may be coupled. In another set of examples, the electrical device 1200 may not include an audio input device 1224 (e.g., microphone) or an audio output device 1208 (e.g., a speaker, a headset, earbuds, etc.), but may include audio input or output device interface circuitry (e.g., connectors and supporting circuitry) to which an audio input device 1224 or audio output device 1208 may be coupled.

The electrical device 1200 may include programmable circuitry 1202 (e.g., one or more processing devices). The programmable circuitry 1202 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1200 may include a memory 1204, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 1204 may include memory that shares a die with the programmable circuitry 1202. This memory may be used as cache memory and may include embedded dynamic random access memory (eDRAM) or spin transfer torque magnetic random access memory (STT-MRAM).

In some examples, the electrical device 1200 may include a communication chip 1212 (e.g., one or more communication chips). For example, the communication chip 1212 may be configured for managing wireless communications for the transfer of data to and from the electrical device 1200. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 1212 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1212 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1212 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1212 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1212 may operate in accordance with other wireless protocols in other examples. The electrical device 1200 may include an antenna 1222 to facilitate wireless communications and/or to receive other wireless communications (such as AM or FM radio transmissions).

In some examples, the communication chip 1212 may manage wired communications, such as electrical, optical, or any other suitable communication protocols (e.g., the Ethernet). As noted above, the communication chip 1212 may include multiple communication chips. For instance, a first communication chip 1212 may be dedicated to shorter-range wireless communications such as Wi-Fi or Bluetooth, and a second communication chip 2312 may be dedicated to longer-range wireless communications such as global positioning system (GPS), EDGE, GPRS, CDMA, WiMAX, LTE, EV-DO, or others. In some examples, a first communication chip 1212 may be dedicated to wireless communications, and a second communication chip 1212 may be dedicated to wired communications.

The electrical device 1200 may include battery/power circuitry 1214. The battery/power circuitry 1214 may include one or more energy storage devices (e.g., batteries or capacitors) and/or circuitry for coupling components of the electrical device 1200 to an energy source separate from the electrical device 1200 (e.g., AC line power).

The electrical device 1200 may include a display 1206 (or corresponding interface circuitry, as discussed above). The display 1206 may include any visual indicators, such as a heads-up display, a computer monitor, a projector, a touchscreen display, a liquid crystal display (LCD), a light-emitting diode display, or a flat panel display.

The electrical device 1200 may include an audio output device 1208 (or corresponding interface circuitry, as discussed above). The audio output device 1208 may include any device that generates an audible indicator, such as speakers, headsets, or earbuds.

The electrical device 1200 may include an audio input device 1224 (or corresponding interface circuitry, as discussed above). The audio input device 1224 may include any device that generates a signal representative of a sound, such as microphones, microphone arrays, or digital instruments (e.g., instruments having a musical instrument digital interface (MIDI) output).

The electrical device 1200 may include a GPS circuitry 1218. The GPS circuitry 1218 may be in communication with a satellite-based system and may receive a location of the electrical device 1200, as known in the art.

The electrical device 1200 may include any other output device 1210 (or corresponding interface circuitry, as discussed above). Examples of the other output device 1210 may include an audio codec, a video codec, a printer, a wired or wireless transmitter for providing information to other devices, or an additional storage device.

The electrical device 1200 may include any other input device 1220 (or corresponding interface circuitry, as discussed above). Examples of the other input device 1220 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1200 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 1200 may be any other electronic device that processes data.

Example methods, apparatus, systems, and articles of manufacture to reduce over-etch are disclosed herein. Further examples and combinations thereof include the following:

Example 1 includes an integrated circuit (IC) package comprising at least one dielectric layer, an interconnect extending at least partially through or from the at least one dielectric layer, and a material on at least a portion of a sidewall of the interconnect, wherein the material comprises at least one of silicon or titanium.

Example 2 includes the IC package as defined in example 1, wherein the material covers at least a portion of an outer diameter of the interconnect.

Example 3 includes the IC package as defined in example 2, wherein a portion of the interconnect not covered by the material includes an indent.

Example 4 includes the IC package as defined in any of examples 1 to 3, wherein the interconnect is a pillar that is laterally surrounded by the material.

Example 5 includes the IC package as defined in example 4, wherein the etch protection material is surrounded by the at least one dielectric layer.

Example 6 includes the IC package as defined in any of examples 1 to 5, wherein the etch protection material comprises silicon nitride.

Example 7 includes the IC package as defined in any of examples 1 to 6, further including first and second dies embedded in the at least one dielectric layer.

Example 8 includes the IC package as defined in example 7, wherein the interconnect is a plated bump for a die bridge that is electrically coupled to the first and second dies.

Example 9 includes a die chip comprising a die, a dielectric, an interconnect extending through at least a portion of the dielectric, the interconnect electrically coupled to the die, and a material on at least a portion of a lateral side of the interconnect, the material including at least one of silicon or titanium.

Example 10 includes the die chip as defined in example 9, wherein the die is a first die, and further including a second die.

Example 11 includes the die chip as defined in example 10, further including a bridge die that is electrically coupled to the first die and the second die.

Example 12 includes the die chip as defined in example 11, wherein the interconnect extends between at least one of the first or second dies and the bridge die.

Example 13 includes the die chip as defined in any of examples 10 to 12, wherein the first die and the second die are carried by a carrier.

Example 14 includes a method comprising defining an interconnect onto a dielectric substrate, applying a material to at least partially cover at least a sidewall of the interconnect, wherein the material comprises at least one of silicon or titanium, and performing an etch process proximate or on the interconnect.

Example 15 includes the method as defined in example 14, wherein the dielectric substrate is a first dielectric substrate, and further including placing a second dielectric substrate onto the first dielectric substrate such that at least a portion of the material is positioned between the interconnect and the second dielectric substrate.

Example 16 includes the method as defined in any of examples 14 or 15, wherein the performing the etch process includes performing a seed layer etch of a seed layer adjacent or proximate to the dielectric substrate.

Example 17 includes the method as defined in any of examples 14 to 16, wherein the interconnect is a first interconnect, and further including coupling a second interconnect between the die and a bridge die.

Example 18 includes the method as defined in any of examples 14 to 17, further including embedding known good dies (KGDs) in the dielectric substrate.

Example 19 includes the method as defined in any of examples 14 to 18, further including applying a thermal treatment to a photoresist to define a gap at least partially surrounding the interconnect, and wherein the material is applied into the gap.

Example 20 includes the method as defined in any of examples 14 to 19, further including etching a photoresist to define a gap at least partially surrounding the interconnect, and wherein the material is applied into the gap.

From the foregoing, it will be appreciated that example systems, methods, apparatus, and articles of manufacture have been disclosed that enable mitigation and/or reduction of over-etching. As a result, examples disclosed herein can enable greater reliability and performance of semiconductor packages and/or devices. Further, examples disclosed herein can enable increased performance by improving signal integrity, for example.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements or method actions may be implemented by, e.g., the same entity or object. Additionally, although individual features may be included in different examples or claims, these may possibly be combined, and the inclusion in different examples or claims does not imply that a combination of features is not feasible and/or advantageous.

The following claims are hereby incorporated into this Detailed Description by this reference. Although certain example systems, methods, apparatus, and articles of manufacture have been disclosed herein, the scope of coverage of this patent is not limited thereto. On the contrary, this patent covers all systems, methods, apparatus, and articles of manufacture fairly falling within the scope of the claims of this patent.

What is claimed is:

1. An integrated circuit (IC) package comprising:
at least one dielectric layer;
an interconnect extending at least partially through or from the at least one dielectric layer; and
a material on at least a portion of a sidewall of the interconnect, wherein the material comprises at least one of silicon or titanium.

2. The IC package as defined in claim 1, wherein the material covers at least a portion of an outer diameter of the interconnect.

3. The IC package as defined in claim 2, wherein a portion of the interconnect not covered by the material includes an indent.

4. The IC package as defined in claim 1, wherein the interconnect is a pillar that is laterally surrounded by the material.

5. The IC package as defined in claim 4, wherein the material is surrounded by the at least one dielectric layer.

6. The IC package as defined in claim 1, wherein the material comprises silicon nitride.

7. The IC package as defined in claim 1, further including first and second dies embedded in the at least one dielectric layer.

8. The IC package as defined in claim 7, wherein the interconnect is a plated bump for a die bridge that is electrically coupled to the first and second dies.

9. A die chip comprising:
a die;
a dielectric;
an interconnect extending through at least a portion of the dielectric, the interconnect electrically coupled to the die; and
a material on at least a portion of a lateral side of the interconnect, the material including at least one of silicon or titanium.

10. The die chip as defined in claim 9, wherein the die is a first die, and further including a second die.

11. The die chip as defined in claim 10, further including a bridge die that is electrically coupled to the first die and the second die.

12. The die chip as defined in claim 11, wherein the interconnect extends between at least one of the first or second dies and the bridge die.

13. The die chip as defined in claim 10, wherein the first die and the second die are carried by a carrier.

14. A method comprising:
defining an interconnect onto a dielectric substrate;
applying a material to at least partially cover at least a sidewall of the interconnect, wherein the material comprises at least one of silicon or titanium; and
performing an etch process proximate or on the interconnect.

15. The method as defined in claim 14, wherein the dielectric substrate is a first dielectric substrate, and further including placing a second dielectric substrate onto the first dielectric substrate such that at least a portion of the material is positioned between the interconnect and the second dielectric substrate.

16. The method as defined in claim 14, wherein the performing the etch process includes performing a seed layer etch of a seed layer adjacent or proximate to the dielectric substrate.

17. The method as defined in claim 14, wherein the interconnect is a first interconnect, and further including coupling a second interconnect between the die and a bridge die.

18. The method as defined in claim 14, further including embedding known good dies (KGDs) in the dielectric substrate.

19. The method as defined in claim 14, further including applying a thermal treatment to a photoresist to define a gap at least partially surrounding the interconnect, and wherein the material is applied into the gap.

20. The method as defined in claim 14, further including etching a photoresist to define a gap at least partially surrounding the interconnect, and wherein the material is applied into the gap.
